(19) United States
(12) Patent Application Publication
(10) Pub. No.: US 2018/0112081 A1
(43) Pub. Date: Apr. 26, 2018

(54) COMPOSITE THERMOELECTRIC MATERIAL AND ITS MANUFACTURING METHOD

(71) Applicants: KABUSHIKI KAISHA TOYOTA CHUO KENKYUSHO, Nagakute-shi (JP); TOCALO CO., LTD., Kobe-shi (JP)

(72) Inventors: Yumi SAIKI, Nagakute-shi (JP); Ryoji ASAHI, Nagakute-shi (JP); Masato MATSUBARA, Nagakute-shi (JP); Noriyuki YASUO, Tokai-shi (JP); Tomohiro NAKASUJI, Akashi-shi (JP)

(73) Assignees: KABUSHIKI KAISHA TOYOTA CHUO KENKYUSHO, Nagakute-shi (JP); TOCALO CO., LTD., Kobe-shi (JP)

(21) Appl. No.: 15/713,000

(22) Filed: Sep. 22, 2017

(30) Foreign Application Priority Data
Oct. 20, 2016 (JP) 2016-205734
Feb. 3, 2017 (JP) 2017-018932
Jun. 20, 2017 (JP) 2017-120361

(51) Int. Cl. C09D 5/08; H01L 37/02; B05D 3/00; C09D 1/00; C01B 25/36

(52) U.S. Cl. CPC C09D 5/084; H01L 37/025; C01B 25/36; C09D 1/00; B05D 3/007

(57) ABSTRACT

A composite thermoelectric material includes: a thermoelectric material of an intermetallic compound series; and a film that is coated over the whole or a part of the surface of the thermoelectric material and contains aluminum phosphate (AlPO₄) as a main component. Such a composite thermoelectric material is obtained by: applying a coating liquid obtained by dispersing or dissolving aluminum phosphate (AlPO₄) into a solvent over the surface of a thermoelectric material; drying the coating liquid and obtaining a precursor film; and firing the thermoelectric material over which the precursor film is formed.

### FIELD OF THE INVENTION

The present invention relates to a composite thermoelectric material and a manufacturing method thereof, and more specifically to a composite thermoelectric material obtained by forming a film to inhibit an element from volatilizing and/or oxidizing over the surface of a thermoelectric material and a manufacturing method thereof.

### BACKGROUND OF THE INVENTION

Thermoelectric materials are classified roughly into intermetallic compound series and nonmetallic series. Among those, the thermoelectric materials of the intermetallic compound series can be manufactured more easily than the thermoelectric materials of the nonmetallic series, and some thermoelectric materials of the intermetallic compound series are known to exhibit thermoelectric properties exceeding the thermoelectric materials of the nonmetallic series depending on the compositions.

A thermoelectric material of an intermetallic compound series, however, sometimes causes a constituent element to volatilize and oxidize when it is exposed to a high temperature. In the case where a thermoelectric material is composed of an intermetallic compound containing an easily-volatilizable element and/or an easily-oxidizable element such as Sb, Mg, Ti, Hf, or Zr in particular, when the thermoelectric material is used at a high temperature, the properties degrade considerably by the volatilization or oxidation of the constituent element. In order to solve the problem accordingly, various proposals have heretofore been offered.

For example, Patent Literature 1 discloses a thermoelectric module formed by surrounding the circumference of a thermoelectric element comprising CoSb₃ by a silica aerogel barrier of a low density.

The literature describes:

(a) whereas a sublimation layer is formed over the surface of CoSb₃ when the CoSb₃ not surrounded by a silica aerogel barrier is heated to a high temperature (700° C., 10⁻⁶ Torr (1.3×10⁻⁴ Pa)), Sb is inhibited from sublimating when the circumference of CoSb₃ is surrounded by a silica aerogel barrier;

(b) the sublimation is inhibited further when an opacifier such as a carbon black, an aluminum oxide, or a titanium dioxide is added to a silica aerogel; and

(c) a silica aerogel of a high density has a higher effect of inhibiting Sb from sublimating than a silica aerogel of a low density but is inferior in heat insulating properties.

Non-Patent Literature 1 discloses a method of:

(a) manufacturing a hybrid silica sol from a commercially-available silica sol and methyltriethoxysilane (MTES);

(b) manufacturing coating slurry containing the hybrid silica sol, a glass frit (main chemical components are SnO and P₂O₅, and small amounts of ZnO and SiO₂ are contained) or alumina particles, and a solvent;

(c) applying the coating slurry over the surface of a skutterudite-based thermoelectric material (CeFe₃CoSb₁₂ or Yb_{0.3}Co₄Sb₁₂) by a slurry blade method; and

(d) solidifying the slurry in a vacuum under the conditions of 373 K and 10 hours and forming a silica-based composite coating over the surface of the thermoelectric material.

The literature describes:

(a) a thick coating layer not having cracking and exfoliation is obtained in the case of a glass frit-hybrid silica coating system;

(b) when a skutterudite-based thermoelectric material to which the composite coating is applied is heat-treated in a vacuum at 873 K for two hours, Sb does not diffuse into the coating layer but a large quantity of Sn diffuses from the coating layer into the thermoelectric material; and

(c) a small quantity of Co—P is generated at the interface between the composite coating and the thermoelectric material.

Non-Patent Literature 2 further discloses a composite thermoelectric material obtained by forming a film in the order of a Ti film and then an Yttria Stabilized Zirconia (YSZ) film over the surface of CoSb₃ by sputtering.

The literature describes:

(a) whereas the surface of CoSb₃ deteriorates by the volatilization of Sb when uncoated CoSb₃ is aged in a vacuum at 650° C. for 24 hours, Sb is inhibited from volatilizing when the surface of CoSb₃ is coated with a YSZ/Ti film;

(b) a crack and an intermetallic compound (TiSb) are not generated in the interface region between the YSZ/Ti film and the CoSb₃ even after the aging; and

(c) whereas the ZT value of the uncoated CoSb₃ deteriorates conspicuously after aging in comparison with a ZT value before aging, the ZT value of CoSb₃ coated with the YSZ/Ti film hardly changes after aging in comparison with a ZT value before aging.

As described in Patent Literature 1, by covering the surface of CoSb₃ with a silica aerogel, Sb can be inhibited from volatilizing to some extent under a high temperature vacuum. The silica aerogel, however, is porous and fragile and is likely to generate a fine crack and hence resistance to Sb volatility can hardly be maintained under an actual usage environment. Further, the silica aerogel is insufficiently effective in inhibiting Sb from volatilizing under a high temperature oxidation atmosphere.

Further, as described in Non-Patent Literature 1, by coating the surface of CoSb₃ with a composite film including a glass frit-hybrid silica, Sb can be inhibited from volatilizing to some extent. Such a composite film, however, is uneven and not dense and hence a thickness of several hundred microns is required in order to obtain resistance to Sb volatility. Moreover, Sn and P react with a thermoelectric material or diffuse even into the interior of a thermoelectric material by heat treatment. Consequently, reproducibility in process and long-term stability have been problems.

Furthermore, as described in Non-Patent Literature 2, by coating the surface of CoSb₃ with a YSZ/Ti film, Sb can be inhibited from volatilizing to some extent under a high temperature vacuum. Since Ti, however, has high electric conductivity, when a Ti film is formed over the surface of a thermoelectric material, electromotive force and temperature difference can hardly be secured. Further, although a dense film is formed by sputtering, a uniform film is hardly formed over the surface of a thermoelectric material having a three-dimensional shape by the sputtering method.

### CITATION LIST

### Patent Literature

[Patent Literature 1] U.S. Pat. No. 7,461,512

### Non-Patent Literature

[Non-Patent Literature 1] J. Alloys and Compounds 527, 247 (2012)
[Non-Patent Literature 2] Corrosion Science 98, 163 (2015)

### SUMMARY OF THE INVENTION

A problem to be solved by the present invention is to provide: a novel composite thermoelectric material obtained by forming a film over the surface of a thermoelectric material of an intermetallic compound series; and a manufacturing method thereof.

Further, another problem to be solved by the present invention is to provide: a composite thermoelectric material capable of inhibiting a constituent element of a thermoelectric material from volatilizing and/or oxidizing even when it is used under a high temperature oxidation atmosphere; and a manufacturing method thereof.

Furthermore, another problem to be solved by the present invention is, in such a composite thermoelectric material: to inhibit a film and a thermoelectric material from reacting with each other; to inhibit a crack from being generated in the film; and/or to inhibit electromotive force and temperature difference from deteriorating by the film.

Moreover, another problem to be solved by the present invention is to provide a manufacturing method of a composite thermoelectric material capable of easily forming such a film even over a thermoelectric material having a complicated shape.

In order to solve the above problems, a composite thermoelectric material according to the present invention includes:

a thermoelectric material of an intermetallic compound series; and

a film that is coated over the whole or a part of the surface of the thermoelectric material and contains aluminum phosphate (AlPO₄) as a main component.

A manufacturing method of a composite thermoelectric material according to the present invention includes:

a coating step of applying a coating liquid obtained by dispersing or dissolving aluminum phosphate (AlPO₄) into a solvent over the surface of a thermoelectric material;

a drying step of drying the coating liquid and obtaining a precursor film; and

a firing step of firing the thermoelectric material over which the precursor film is formed and obtaining the composite thermoelectric material according to the present invention.

Aluminum phosphate has a high melting point of 1,800° C. and high thermal stability. When a dense film containing the aluminum phosphate as a main component is formed over the surface of a thermoelectric material, the film blocks the oxygen in the atmosphere and inhibits a constituent element contained in the thermoelectric material from volatilizing. Further, an aluminum phosphate film has high thermal stability and hence never reacts with the thermoelectric material.

Furthermore, when the thickness of a film is optimized, neither a pinhole is generated in the film nor the exfoliation of the film and a crack in the film are generated by a thermal stress. Moreover, since the film contains aluminum phosphate as a main component, the electromotive force and temperature difference of the thermoelectric material are never reduced.

Such a film can be obtained by applying a coating liquid containing aluminum phosphate over the surface of a thermoelectric material and drying and firing a coating layer. A coating method is less expensive than a sputtering method and can be applied easily even over an indented surface. In addition, even in the state of an element in which a thermoelectric member and an electrode are joined, the surface of the thermoelectric member can be coated together with the electrode joint portion. As a result, not only the surface of a thermoelectric member can be protected but also the reliability of an electrode and a joint can be improved at a low cost.

### BRIEF DESCRIPTION OF THE DRAWINGS

FIG. 1 shows cross-sectional photographs of composite thermoelectric materials (Comparative Examples 1 to 4) obtained by forming various films over the surfaces of CoSb₃-based thermoelectric materials before and after oxidation treatment tests;

FIG. 2 shows cross-sectional photographs of composite thermoelectric materials (Examples 1 and 2 and Comparative Example 5) obtained by forming various films over the surfaces of CoSb₃-based thermoelectric materials before and after oxidation treatment tests;

FIG. 3 shows cross-sectional photographs of composite thermoelectric materials obtained by forming AlPO₄ films over the surfaces of CoSb₃-based thermoelectric materials (Examples 3 and 4), a (Ti, Zr, Hf)NiSn-based half-Heusler (Example 5), and an Mg₂ (Si, Sn)-based silicide (Example 6) before and after oxidation treatment tests; and

FIG. 4 shows cross-sectional photographs of composite thermoelectric materials obtained by forming AlPO₄ films over the surfaces of Bi₂Te₃-based thermoelectric materials (Examples 7 and 8) before and after oxidation treatment tests.

### DETAILED DESCRIPTION OF THE PREFERRED EMBODIMENTS

An embodiment according to the present invention is hereunder explained in detail.

### [1. Composite Thermoelectric Material]

A composite thermoelectric material according to the present invention includes:

a thermoelectric material of an intermetallic compound series; and

a film that is coated over the whole or a part of the surface of the thermoelectric material and contains aluminum phosphate (AlPO₄) as a main component.

### [1.1. Thermoelectric Material]

A thermoelectric material includes an intermetallic compound. In the present invention, the composition of an intermetallic compound is not particularly limited, and the present invention can be applied to every thermoelectric material of an intermetallic compound series.

As a thermoelectric material, an intermetallic compound containing an easily-volatilizable element and/or an easily-oxidizable element is preferably used in particular. When the present invention is applied to such a thermoelectric material, a high effect can be obtained.

Here, an “easily-volatilizable element” means an element having an equilibrium temperature of 700° C. or less at a vapor pressure of 10 Pa, for example Li, Na, Ca, Mg, P, S, K, Zn, Se, Sr, Cd, Sb, Te, Eu, or Yb.

An “easily-oxidizable element” means an element having a standard oxidation-reduction potential (E₀) of a metal of −1 V or less, for example Li, K, Ba, Sr, Ca, Na, Mg, Al, Ti, Zr, Hf, or Mn.

Examples of an easily-volatilizable element or an easily-oxidizable element include Sb, Mg, Ti, Hf, Zr, Li, Na, Ca, P, S, K, Zn, Se, Sr, Cd, Te, Eu, Yb, Ba, Al, or Mn. A thermoelectric material may contain either a kind or two or more kinds of those elements.

Specific examples of thermoelectric materials of intermetallic compound series include:

(a) R(Fe, Co) Sb₁₂-based thermoelectric materials (here, R is at least one element selected from the group consisting of La, Ba, Yb, Ca, In, Al, Ga, Ti, Zr, and Hf);

(b) half-Heusler materials: ANiSn, ACoSb (A is Ti, Zr, or Hf);

(c) chalcogenide compounds: ZnSb, Bi₂(Sb, Te)₃, PbTe, La₃Te₄, PbSe, Sb₂Se₃, Bi₂Se₃, Ag₂Te, Yb₁₄MnSb₁₁, (GeTe)₁₋ₓ(AgSbTe₂)ₓ, Cu—Sb—Se, Cu—Sb—S, Cu—Sn—S, Cu₂₋ₓSe, Cu₂₋ₓS, Cu₂₋ₓTe;

(d) silicides: Mg₂(Si, Sn); and

(e) clathrates: Ba₈Ga₁₆Ge₃₀, Sr₈Ga₁₆Ge₃₀.

Among those, an R(Fe, Co)Sb₁₂-based thermoelectric material is an intermetallic compound called a filled skutterudite, and has a crystal structure in which the center part of a basket formed by Co and Sb is filled with a filling element R. A filling element R packed in a basket vibrates at a natural frequency and can reduce thermal conductivity κ by resonantly scattering lattice oscillation (rattling effect).

Co₄Sb₁₂ not containing a filling element R is a p-type thermoelectric material. Since a filling element R is an electron dopant, a filled skutterudite RₓCo₄Sb₁₂ is an n-type semiconductor. A filling element R is effective for increasing electric conductivity σ and decreasing thermal conductivity κ, but the degrees of the effects vary in accordance with the type of the element. Meanwhile, Fe with which a Co site is substituted is a hole dopant.

When a plurality of filling elements R having different effects are combined and simultaneously a part of a Co site is substituted with Fe, a carrier concentration is optimized and also thermal conductivity κ decreases. As a result, a high thermoelectric property (ZT≥1) is obtained.

A filled skutterudite-based compound, however, contains Sb that is likely to volatilize as a main constituent element even though it essentially has a high thermoelectric property and hence a problem has been that durability is low under an actual usage environment (under a high temperature oxidation atmosphere). In contrast, when the present invention is applied to a filled skutterudite-based compound, the deterioration of a thermoelectric property caused by the volatilization and oxidation of Sb can be inhibited even under a high temperature oxidation atmosphere.

### [1.2. Film]

### [1.2.1. Composition of Film]

A film contains aluminum phosphate (AlPO₄) as a main component. Here, “to contain aluminum phosphate as a main component” means that a content of the aluminum phosphate contained in a film is 75 wt % or more.

A film can be obtained by applying a solution in which the whole or a part of aluminum phosphate dissolves over a substrate surface and heat-treating a coating layer at a relatively low temperature. For the reason, a film takes an amorphous state (a state where units of aluminum phosphate form a network vitreously) in many cases.

A film may contain unavoidable impurities. For example, when a film is formed by a method to be described later, a small quantity of Al(OH)₃ may be contained sometimes. Al(OH)₃ is estimated to be generated by decomposing a part of aluminum phosphate. An Al(OH)₃ concentration in a coating liquid is about 2 to 4 wt % in some cases.

Further, a film may contain various additives. For example, in the case of forming a film by a method to be described later, the thickness of the film can be increased by adding an appropriate quantity of SiC powder into a coating liquid.

When the contents of an additive and unavoidable impurities are excessive, however, the effect of inhibiting volatilization and oxidation may deteriorate in some cases. Further, when the quantity of an additive having the function of increasing the electric conductivity of a film is excessive, that causes electromotive force and temperature difference to lower.

For the reason, the larger the quantity of aluminum phosphate contained in a film, the better. A content of aluminum phosphate contained in a film is desirably 80 wt % or more, more desirably 90 wt % or more, and even more desirably 95 wt % or more. By using a method to be described later, a film including aluminum phosphate substantially with the balance made up of unavoidable impurities is obtained.

[1.2.2. Place where Film is Formed]

A film may be coated over either the whole surface or a part of a thermoelectric material. A thermoelectric material is usually processed into a rod-like member, and an end of the rod-like member is heated to a high temperature, and the other end is retained at a low temperature. For the reason, a film may be coated at least to a region where the volatilization and oxidation of a constituent element are problems.

Specifically, a film is preferably coated at least to a region where a temperature rises to 500° C. or more during usage over the surface of a thermoelectric material.

### [1.2.3. Thickness of Film]

The thickness of a film is not particularly limited and an optimum thickness can be selected in accordance with the purpose. In general, when a film is too thin, the effect of inhibiting the volatilization and oxidation of a constituent element is insufficient. A thickness of a film is therefore desirably 0.7 μm or more.

In contrast, when a film is too thick, not only the effect of inhibiting volatilization and oxidation is saturated but also a pinhole and a crack may be generated in the film in some cases. A thickness of a film therefore is desirably 2.0 μm or less. A thickness of a film is more desirably less than 1.5 μm.

### [2. Manufacturing Method of Composite Thermoelectric Material]

A manufacturing method of a composite thermoelectric material according to the present invention includes:

a coating step of applying a coating liquid obtained by dispersing or dissolving aluminum phosphate (AlPO₄) into a solvent over the surface of a thermoelectric material;

a drying step of drying the coating liquid and obtaining a precursor film; and

a firing step of firing the thermoelectric material over which the precursor film is formed and obtaining the composite thermoelectric material according to the present invention.

### [2.1. Coating Step]

Firstly, a coating liquid obtained by dispersing or dissolving aluminum phosphate (AlPO₄) into a solvent is applied over the surface of a thermoelectric material (coating step).

### [2.1.1. Coating Liquid]

### [A. Solvent]

A solvent contained in a coating liquid is not particularly limited and an optimum solvent can be used in accordance with the purpose. Usually a mixed solvent of water and ethanol is used from the viewpoint of cost and handleability.

### [B. Aluminum Phosphate]

When a quantity of aluminum phosphate contained in a coating liquid is too small, a dense film is hardly formed by one-time coating. A content of aluminum phosphate in a coating liquid therefore is desirably 20 wt % or more. A content of aluminum phosphate is more desirably 30 wt % or more.

In contrast, when a quantity of aluminum phosphate is excessive, the viscosity of a coating liquid increases excessively and a uniform film is hardly formed. A content of aluminum phosphate in a coating liquid therefore is desirably 60 wt % or less. A content of aluminum phosphate is more desirably 40 wt % or less.

A particle size of aluminum phosphate is not particularly limited but, in order to form a thin and uniform film, the smaller the particle size of aluminum phosphate, the better. Specifically, an average particle size of aluminum phosphate is preferably 100 nm or less.

### [C. Another Component]

Another component may be contained in a coating liquid as long as a film having aforementioned composition and functions can be formed. Examples of other components include:

(a) an additive for forming a thick film (for example, SiC powder, SiO₂ powder, or the like);

(b) aluminum hydroxide; and

(c) nitric acid for adjusting pH and making aluminum phosphate soluble.

### [2.1.2. Coating Method]

A coating method of a coating liquid is not particularly limited. Examples of coating method include a spray atomization method, a dipping method, or the like. Further, coating may be applied either only one time or two or more times. Furthermore, coating/drying/firing may be applied either only one time or two or more times repeatedly.

### [2.2. Drying Step]

Successively, the coating liquid is dried and a precursor film is obtained (drying step). A drying condition is not particularly limited and any condition is acceptable as long as the solvent can be volatilized and the uniform precursor film can be formed. Usually, drying is carried out at a temperature of 100° C. or less.

### [2.3. Firing Step]

Successively, the thermoelectric material over which the precursor film is formed is fired, and the composite thermoelectric material according to the present invention is obtained (firing step).

Firing is applied for densifying the precursor film. Usually, when a firing temperature is excessively low and/or a firing time is excessively short, a dense film is not obtained. In contrast, when a firing temperature is excessively high and/or a firing time is excessively long, not only there are no practical benefits but also a film may react with a thermoelectric material in some cases.

As an optimum firing condition, a firing temperature of 300° C. or more is desirable although it depends on the composition of a thermoelectric material. Firing time is desirably 30 minutes to 12 hours and more desirably 30 minutes to one hour. An atmosphere during firing is not particularly limited. Usually, firing is carried out in the atmosphere.

### [3. Thermoelectric Element and its Manufacturing Method]

A thermoelectric element usually takes a structure formed by arranging a p-type thermoelectric member (leg part) of a columnar shape and an n-type thermoelectric member (leg part) of a columnar shape in parallel and jointing ends of them with electrodes (a π-shaped structure) in many cases. Further, a thermoelectric element also sometimes takes a structure formed by arranging over an x-y plane and joining in series such π-shaped structures, or a structure formed by arranging over an x-y plane and simultaneously stacking also in the z-axis direction such π-shaped structures (a cascade-shaped structure).

In the present invention, a structure of a thermoelectric element is not particularly limited. That is, a composite thermoelectric material according to the present invention can be applied to a thermoelectric element having any structure.

When a thermoelectric element is manufactured by using a composite thermoelectric material according to the present invention, jointing of a thermoelectric member and an electrode may be carried out either before or after a film is formed. When a film is formed in advance and then a thermoelectric member and an electrode are jointed, however, a film in the vicinity of the interface may exfoliate undesirably. For the reason, a film may preferably be formed after a thermoelectric member and an electrode are jointed.

### [4. Effects]

Aluminum phosphate has a high melting point of 1,800° C. and high thermal stability. When a dense film containing the aluminum phosphate as a main component is formed over the surface of a thermoelectric material, the film blocks the oxygen in the atmosphere and inhibits a constituent element contained in the thermoelectric material from volatilizing. Further, an aluminum phosphate film has high thermal stability and hence never reacts with the thermoelectric material.

Furthermore, when the thickness of a film is optimized, neither a pinhole is generated in the film nor the exfoliation of the film and a crack in the film are generated by a thermal stress. Moreover, since the film contains aluminum phosphate as a main component, the electromotive force and temperature difference of the thermoelectric material are never reduced.

Such a film can be obtained by applying a coating liquid containing aluminum phosphate over the surface of a thermoelectric material and drying and firing a coating layer. A coating method is less expensive than a sputtering method and can be applied easily even over an indented surface. In addition, even in the state of an element in which a thermoelectric member and an electrode are joined, the surface of the thermoelectric member can be coated together with the electrode joint portion. As a result, not only the surface of a thermoelectric member can be protected but also the reliability of an electrode and a joint can be improved at a low cost.

For example, an R(Fe, Co)₄Sb₁₂-based thermoelectric material is known as having highest thermoelectric performance in the temperature range between 550° C. to 600° C. It is also known, however, that, when such a material is used in a high temperature range, Sb gradually volatilizes and a thermoelectric property deteriorates. In contrast, when a dense aluminum phosphate film is formed over the surface of an R(Fe, Co)₄Sb₁₂-based thermoelectric material, a thermoelectric property does not deteriorate even when the material is retained at 600° C. for 24 hours in the atmosphere, and a good interface and a good thermoelectric property can be maintained.

Even when a thermoelectric material contains an easily-volatilizable element or an easily-oxidizable element other than Sb, an effect similar to a thermoelectric material containing Sb can be obtained. This is presumably based on the following reasons.

That is, aluminum phosphate has a high melting point of 1,800° C. and is stable, has high block ability against oxygen and an easily-volatilizable element, and functions as a corrosion resistant film having good affinity with the surface of an R(Fe, Co)₄Sb₁₂-based thermoelectric material. Similarly to another phosphate, aluminum phosphate also has good affinity with most metals such as Fe, Cu, Mn, and Ti, and hence becomes a film effective for a thermoelectric material containing an easily-volatilizable element or an easily-oxidizable element other than Sb.

### EXAMPLES

### Examples 1 and 2, Comparative Examples 1 to 5

### [1. Manufacturing of Specimen]

Various kinds of coating materials are formed over the surfaces of CoSb-based thermoelectric materials (hereunder referred to merely as “substrates”). The outlines of processing methods are as follows.

(1) As Comparative Example 1, an Al₂O₃ film was formed over the surface of a substrate by using an atmospheric plasma spraying method. The substrate temperature during thermal spraying was set at 200° C. or less.

(2) As Comparative Example 2, a chromic acid aqueous solution was applied over the surface of a substrate, and successively fired at a temperature of 500° C. or more. CrO₃ contained in the aqueous solution became Cr₂O₃ by the firing. The processing is used for the applications requiring wear resistance and corrosion resistance because a film is hard and dense. A film thickness is usually about 0.5 to 20 μm. The substrate temperature during processing was set at about 550° C.

(3) As Comparative Examples 3 and 4 for forming a silica-based thin film, a solution containing a silica precursor was applied over the surface of a substrate, and successively fired at a temperature of 500° C. or less. The processing is used as processing for forming a film requiring corrosion resistance and antifouling property because the film is dense and in addition has hydrophilicity. A film thickness is usually about 0.5 to 2 μm. A film thickness was controlled by a silica concentration in a solution. The substrate temperature during processing was set at about 450° C. or 250° C.

(4) As Examples 1 and 2, a coating liquid containing aluminum phosphate was applied over the surface of a substrate, and dried and fired. A film thickness was controlled by an aluminum phosphate concentration in a solution and the frequency of coating. The firing temperature of a film was set at 300° C.

(5) As Comparative Example 5, a coating liquid containing SiC powder and aluminum phosphate (50:50 by weight ratio) was applied over the surface of a substrate, and dried and fired. The firing temperature of a film was set at 300° C.

### [2. Test Method]

The smoothness of a substrate over which each of the various films was formed was evaluated by visual observation and cross-section observation using Scanning Electron Microscopy (SEM).

An oxidation treatment was carried out in which a substrate over which each of the various films was formed was retained at 550° C. for one hour or at 600° C. for 24 hours in the atmosphere. The interface between a film and a substrate before and after the treatment was observed by SEM.

### [3. Result]

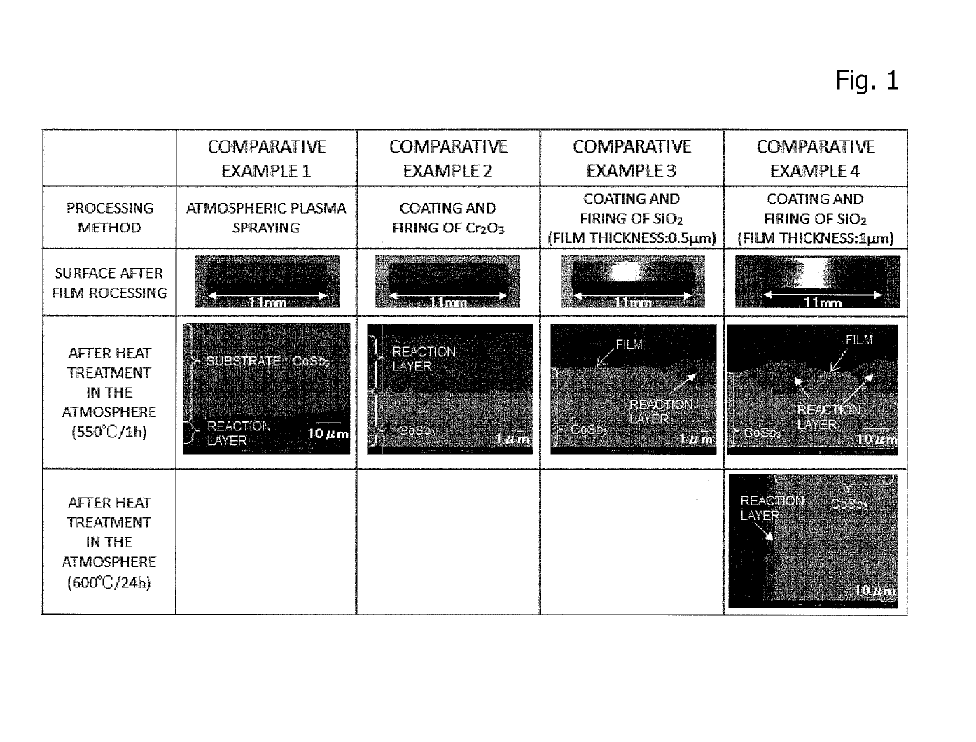

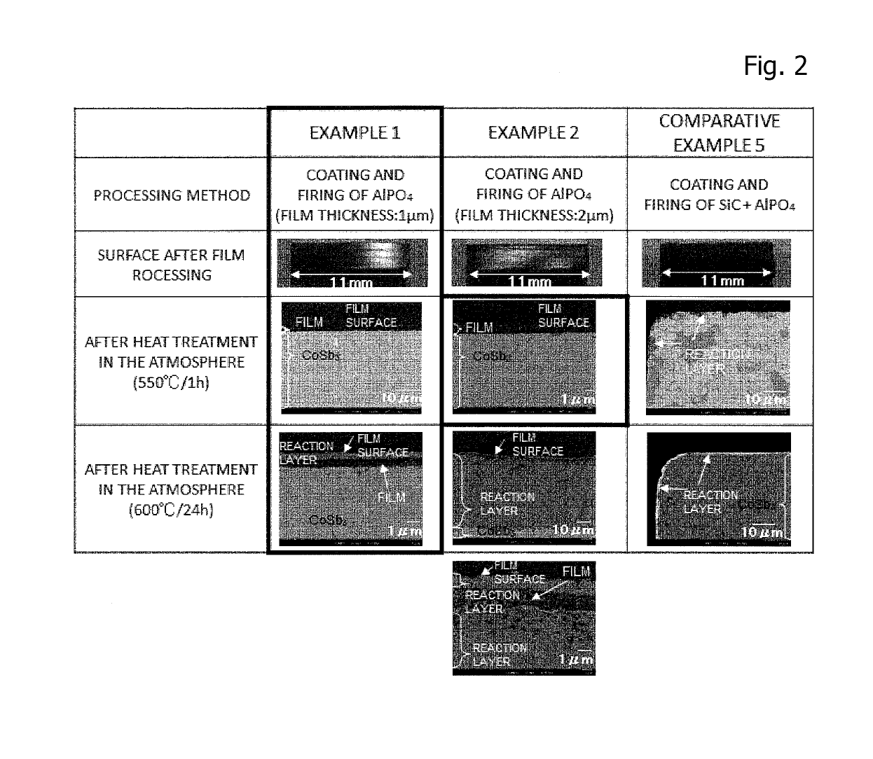

FIGS. 1 and 2 show cross-sectional photographs of composite thermoelectric materials obtained by forming various films over the surfaces of CoSb₃-based thermoelectric materials before and after oxidation treatment tests. Further, Table 1 shows various coating conditions applied, smoothness, and oxidation resistance. The following results are obtained from FIGS. 1 and 2 and Table 1.

TABLE 1

| | Comparative | Comparative | Comparative | Comparative | | | Comparative |
|---|---|---|---|---|---|---|---|
| | Example 1 | Example 2 | Example 3 | Example 4 | Example 1 | Example 2 | Example 5 |
| Processing name | Atmospheric | Coating and | Coating and | Coating and | Coating and | Coating and | Coating and |
| | plasma | firing | firing | firing | firing | firing | firing |
| | spraying | | | | | | |
| Main component of film | Al₂O₃ | Cr₂O₃ | SiO₂ | SiO₂ | AlPO₄ | AlPO₄ | SiC + AlPO₄ |
| Actual film thickness | 100 to 300 | 0.5 or less | 0.5 | 1 | 0.7 to 1.0 | 1.5 to 2.0 | 50 to 100 |
| (μm) | | | | | | | |
| Substrate temperature | 200 or less | aboout 550 | about 450 | 250 | 300 | 300 | 300 |
| or firing tempeature (° C.) | | | | | | | |
| Smoothness of specimen | x | Δ | ∘ | ∘ | ∘ | ∘ | X |
| surface after processing | | | | | | | |
| Oxidation resistance of | x | x | Δ | Δ | ∘ | ∘ T ≤ 550° C. | Δ |
| thermoelectric material | | | | | | x T ≥ 600° C. | |
| Content of AlPO₄ (%) | 0 | 0 | 0 | 0 | 20 to 30 | 20 to 30 | 10 to 20 |
| (in coating liquid) | | | | | | | |
| Content of AlPO₄ (%) | 0 | 0 | 0 | 0 | 80 to 97 | 80 to 97 | 13 to 28 |
| (in film) | | | | | | | |

Here, with regard to the smoothness in Table 1:

“o” shows that a surface is smooth even under microscopic observation;

“Δ” shows that a surface looks like smooth visually but unevenness is recognized under microscopic observation; and

“x” shows that unevenness is recognized on a surface when observed visually.

Further, with regard to oxidation resistance:

“o” shows that the thickness of a reaction layer is 10 μm or less in most of a region of a specimen surface (80% or more of the surface area of a specimen);

“Δ” shows that the thickness of a reaction layer is 10 μm or more in a partial region of a specimen surface (20% to 80% of the surface area of a specimen); and

“x” shows that the thickness of a reaction layer is 10 μm or more in most of a region of a specimen surface (80% or more of the surface area of a specimen).

(1) A film of Comparative Example 1 or 2 has no oxidation resistance, and it is observed clearly that a substrate touching a coating material reacts with oxygen even in the case of oxidation treatment at 550° C. for one hour (refer to FIG. 1). Further, in the case of ceramic (Al₂O₃) thermal spraying, the damage of a substrate surface is significant and the smoothness lowers conspicuously.

(2) In the case of a film of Comparative Example 3 or 4, a substrate is oxidized partially by the oxidation treatment at 550° C. for one hour regardless of a film thickness. This is presumably because a fine pinhole or crack is generated in a film.

(3) A film of Example 1 or 2 shows smoothness of about 1 μm and a good oxidation resistance. In oxidation treatment at 550° C. for one hour in particular, a reaction layer is not recognized regardless of a film thickness.

When a film thickness is increased to about 2 μm (Example 2), a reaction layer is generated by the oxidation treatment at 600° C. for 24 hours. This is presumably because a pinhole or a crack is caused by the increase of the film thickness.

In contrast, when a film thickness is 1 μm (Example 1), the quantity of a generated reaction layer is very small even by oxidation treatment at 600° C. for 24 hours. Further, a substrate existing right under a film almost maintains the composition immediately after the manufacturing.

(4) The film thickness of Comparative Example 5 is increased by adding SiC frit. As a result, smoothness is hindered accordingly and oxidation resistance also deteriorates. This is presumably because a break and a crack are caused in a film by a thermal stress.

### Examples 3 to 6

### [1. Manufacturing of Specimen]

A coating liquid containing aluminum phosphate was applied over the surface of a substrate, and dried and fired. As a substrate, a CoSb-based thermoelectric material (Example 3 or 4), a (Ti, Zr, Hf)NiSn-based half-Heusler (Example 5), or an Mg₂ (Si, Sn)-based silicide (Example 6) was used. A film thickness was controlled by an aluminum phosphate concentration in a solution and the frequency of coating. The firing temperature of a film was set at 380° C.

### [2. Test Method]

The smoothness of a substrate over which a film was formed was evaluated by visual observation and cross-section observation using SEM.

An oxidation treatment was carried out in which a substrate over which a film was formed was retained at 550° C. for one hour or at 600° C. for 24 hours in the atmosphere. The interface between a film and a substrate before and after the treatment was observed by SEM.

### [3. Result]

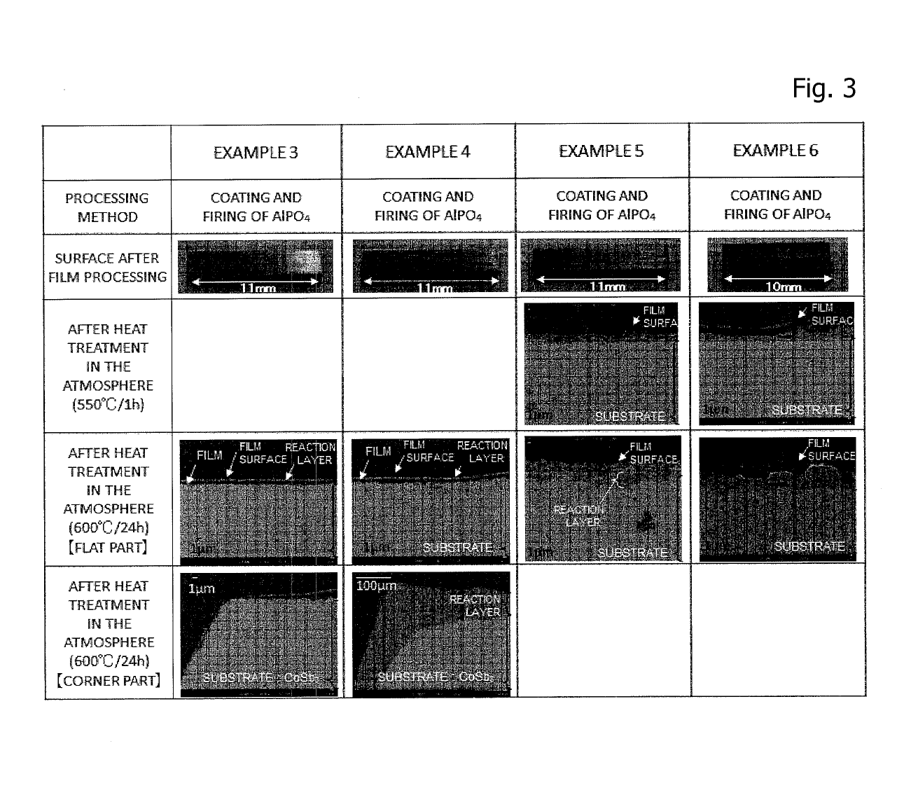

FIG. 3 shows cross-sectional photographs of composite thermoelectric materials obtained by forming AlPO₄ films over the surfaces of CoSb₃-based thermoelectric materials (Examples 3 and 4), a (Ti, Zr, Hf)NiSn-based half-Heusler (Example 5), and an Mg₂ (Si, Sn)-based silicide (Example 6) before and after oxidation treatment tests. Further, Table 2 shows various coating conditions applied, smoothness, and oxidation resistance. Here, in Table 2, the evaluation methods of smoothness and oxidation resistance are similar to Table 1. The following results are obtained from FIG. 3 and Table 2.

TABLE 2

| | Example 3 | Example 4 | Example 5 | Example 6 |
|---|---|---|---|---|
| Processing name | Coating and | Coating and | Coating and | Coating and |
| | firing | firing | firing | firing |
| Main component of film | AlPO₄ | AlPO₄ | AlPO₄ | AlPO₄ |
| Actual film thickness | 0.8 to 1 | 1.2 to 1.5 | 0.8 to 1.5 | 1 to 4 |
| (μm) | (before firing) | (before firing) | (before firing) | (before firing) |
| Substrate temperature | 380 | 380 | 380 | 380 |
| or firing temperature | | | | |
| (° C.) | | | | |
| Smoothness of specimen | ◯ | Δ | ◯ | Δ |
| surface after processing | | | | |
| Oxidation resistance of | ◯ | ◯ | ◯ | ◯ |
| thermoelectric material | | | | |
| Content of AlPO₄ (%) | 30 to 40 | 40 to 50 | 20 to 30 | 20 to 30 |
| (in coating liquid) | | | | |
| Content of AlPO₄ (%) | 80 to 97 | 80 to 97 | 80 to 97 | 80 to 97 |
| (in film) | | | | |

(1) By coating an AlPO₄ film, the oxidation resistance of not only a CoSb₃-based thermoelectric material but also a (Ti, Zr, Hf)NiSn-based half-Heusler and an Mg₂(Si, Sn)-based silicide improves.

(2) When an AlPO₄ film is formed over the surface of a CoSb₃-based thermoelectric material by using a coating liquid having an AlPO₄ concentration of 30 to 40 wt % (Example 3), a very good oxidation resistance is exhibited. That is, a reaction layer is hardly formed at not only the flat part but also a corner part of a substrate.

(3) When an AlPO₄ film is formed over the surface of a CoSb₃-based thermoelectric material by using a coating liquid having an AlPO₄ concentration of 40 to 50 wt % (Example 4), the oxidation resistance is good but the smoothness of the specimen surface somewhat deteriorates. This is presumably because the content of AlPO₄ in the coating liquid is high and hence the uniformity of the film deteriorates.

(4) When an AlPO₄ film is formed over the surface of an Mg₂(Si, Sn)-based silicide by using a coating liquid having an AlPO₄ concentration of 20 to 30 wt % (Example 6), the oxidation resistance is good but the smoothness of the specimen surface somewhat deteriorates. This is presumably because the coating liquid reacts with the Mg₂(Si, Sn)-based silicide while the film is formed.

(5) Even in the case of another material described in the present invention, the oxidation resistance of a film including a corner part can be improved by appropriately adjusting an AlPO₄ concentration as shown in the present example.

### Examples 7 and 8

### [1. Manufacturing of Specimen]

A coating liquid containing aluminum phosphate was applied over the surface of a substrate, and dried and fired. As a substrate, a Bi₂Te₃-based thermoelectric material (Example 7 or 8) was used. Here, the substrates used in Examples 7 and 8 have nearly identical compositions although the quantities of the doping elements are somewhat different. A film thickness was controlled by an aluminum phosphate concentration in a solution and the frequency of coating. The firing temperature of a film was set at 380° C.

### [2. Test Method]

The smoothness of a substrate over which a film was formed was evaluated by visual observation and cross-section observation using SEM.

An oxidation treatment was carried out in which a substrate over which a film was formed was retained at 350° C. for 24 hours in the atmosphere. The interface between a film and a substrate before and after the treatment was observed by SEM.

### [3. Result]

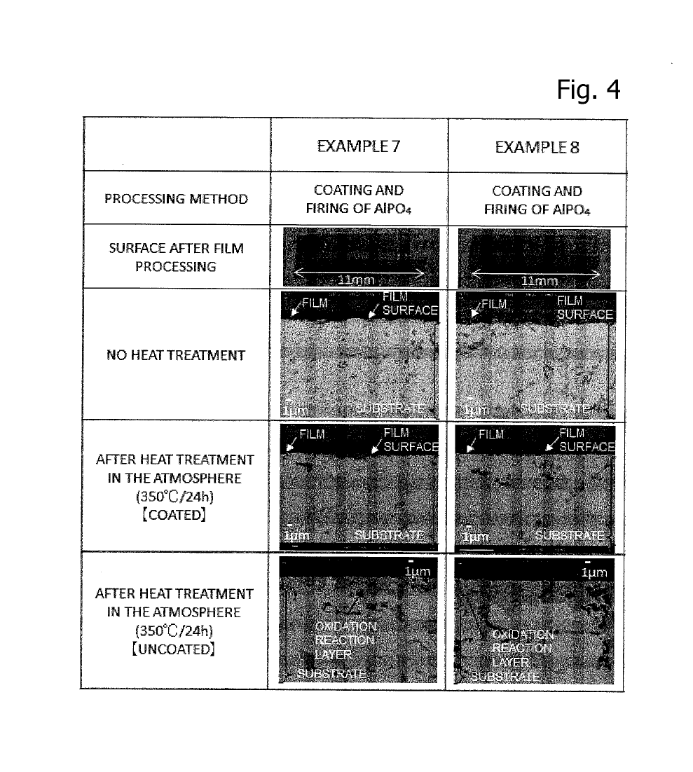

FIG. 4 shows cross-sectional photographs of composite thermoelectric materials obtained by forming AlPO₄ films over the surfaces of Bi₂Te₃-based thermoelectric materials (Examples 7 and 8) before and after oxidation treatment tests. Here, the lower part of FIG. 4 also shows cross-sectional photographs of Bi₂Te₃-based thermoelectric materials over which no AlPO₄ films are formed (uncoated) after oxidation treatment tests. Further, Table 3 shows various coating conditions applied, smoothness, and oxidation resistance. Here, in Table 3, the evaluation methods of smoothness and oxidation resistance are similar to Table 1. The following results are obtained from FIG. 4 and Table 3.

TABLE 3

| | Example 7 | Example 8 |
|---|---|---|
| Processing name | Coating and firing | Coating and firing |
| Main component of film | AlPO₄ | AlPO₄ |
| Actual film thickness | 0.8 to 1 | 2 to 3 |
| (μm) | (before firing) | (befroe firing) |
| Substrate temperature | 380 | 380 |
| or firing temperature | | |
| (° C.) | | |
| Smoothness of specimen | Δ | Δ |
| surface after processing | | |
| Oxidation resistance of | ◯ | ◯ |
| thermoelectric material | | |
| Content of AlPO₄ (%) | 30 to 40 | 40 to 50 |
| (in coating liquid) | | |
| Content of AlPO₄ (%) | 80 to 97 | 80 to 97 |
| (in film) | | |

(1) In the case of uncoated, an oxidation reaction layer is formed over a surface when heat treatment is applied at 350° C. in the atmosphere. In the case of uncoated further, the thicknesses of the oxidation reaction layers are different although the compositions are nearly identical between Example 7 and Example 8. This is presumably because variations exist between specimens or variations exist among sites even in an identical specimen.

(2) In the case of coated, good oxidation resistance is shown in both Examples 7 and 8. No oxidation reaction layer is recognized over a specimen surface even after oxidation treatment tests.

Although an embodiment according to the present invention has heretofore been explained in detail, the present invention is not limited to the above embodiment at all and can be modified variously in the range not departing from the tenor of the present invention.

A composite thermoelectric material according to the present invention can be used for: various kinds of thermoelectric generators such as a solar power generator, a seawater temperature-difference thermoelectric generator, a fossil fuel thermoelectric generator, and a regenerative power generator of factory waste heat or automobile exhaust heat; a precise temperature control device; a constant-temperature unit; heating and cooling equipment; a refrigerator; and an electric power source for watches and clocks.

What is claimed is:

1. A composite thermoelectric material comprising:
a thermoelectric material of an intermetallic compound series; and
a film that is coated over the whole or a part of the surface of the thermoelectric material and contains aluminum phosphate (AlPO₄) as a main component.

2. The composite thermoelectric material according to claim 1, wherein the film is coated at least to a region where a temperature rises to 500° C. or more during usage over the surface of the thermoelectric material.

3. The composite thermoelectric material according to claim 1, wherein a content of the aluminum phosphate contained in the film is 80 wt % or more.

4. The composite thermoelectric material according to claim 1, wherein the thermoelectric material contains an easily-volatilizable element and/or an easily-oxidizable element.

5. The composite thermoelectric material according to claim 1, wherein the thermoelectric material contains at least one element selected from the group consisting of Sb, Mg, Ti, Hf, Zr, Li, Na, Ca, P, S, K, Zn, Se, Sr, Cd, Te, Eu, Yb, Ba, Al, and Mn.

6. The composite thermoelectric material according to claim 1, wherein the thermoelectric material includes an R(Fe, Co) Sb₁₂-based thermoelectric material (here, R is at least one element selected from the group consisting of La, Ba, Yb, Ca, In, Al, Ga, Ti, Zr, and Hf).

7. The composite thermoelectric material according to claim 1, wherein the thickness of the film is in the range of 0.7 μm to 2.0 μm.

8. A manufacturing method of a composite thermoelectric material including:
a coating step of applying a coating liquid obtained by dispersing or dissolving aluminum phosphate (AlPO₄) into a solvent over the surface of a thermoelectric material;
a drying step of drying the coating liquid and obtaining a precursor film; and
a firing step of firing the thermoelectric material over which the precursor film is formed and obtaining the composite thermoelectric material according to claim 1.

9. The manufacturing method of a composite thermoelectric material according to claim 8, wherein the quantity of the aluminum phosphate contained in the coating liquid is in the range of 20 wt % to 60 wt %.
